(19) United States
(12) Patent Application Publication
(10) Pub. No.: US 2008/0199614 A1
(43) Pub. Date: Aug. 21, 2008

(54) Method for improving atomic layer deposition performance and apparatus thereof

(75) Inventors: Ming-Yen Li, Fongshan City (TW); Hsiao-Che Wu, Chung-Li City (TW)

Correspondence Address: Joe McKinney Muncy, PO Box 1364, Fairfax, VA, 22038-1364, US

(73) Assignee: ProMOS Technologies Inc.

(21) Appl. No.: 11/790,432

(22) Filed: Apr. 25, 2007

(30) Foreign Application Priority Data
Feb. 15, 2007 (TW) 96105846

(51) Int. Cl. C23C 16/00

(52) U.S. Cl. 427/255.34; 118/715; 427/255.28; 427/255.36

(57) ABSTRACT

A method for improving atomic layer deposition (ALD) performance and an apparatus thereof are disclosed. The apparatus alternates the process temperature of the different ALD steps rapidly, and the process temperature of each step is determined in accordance with the specific precursor and the substrate surface used. In case a higher process temperature is needed, a plurality of heating units of the apparatus increases and keeps the temperature of the deposited substrate to complete surface reaction. When the lower process temperature is needful for the next ALD step, the heating units are turned off to reduce the temperature of the deposited substrate and a gas flow puffed to the heater and the deposited substrate to assist in temperature cooling.

### BACKGROUND

1. Field of Invention

The present invention relates to a method of atomic layer deposition and an apparatus thereof. More particularly, the present invention relates to a deposition method for improving the atomic layer deposition performance.

2. Description of Related Art

Atomic layer deposition (ALD) is a unique method for depositing thin films with high quality. Compared with other film deposition methods, the atomic layer deposition method has the following benefits, excellent step coverage performance, superb conformality, low impurity content and precise thickness control.

ALD is can closely relate to chemical vapor deposition (CVD) technique. The difference between the ALD and the CVD technique is that in the ALD technique the substrate for deposition is alternately exposed to only one of several complementary chemical environments and controlled within an appropriate temperature range to accomplish the films deposition. In the interval between pulsing the gaseous precursors to the substrate, generally, an inert gas is introduced to the chamber to purge the excess reactant of each pulse step.

The self-limiting film growth process of the ALD performs a selective chemisorption between gaseous precursor and substrate surface and forms a film with atomic-scale thickness control. One ALD cycle of aluminum oxide (Al₂O₃) deposition is can be a typical example of ALD surface reaction. Firstly a substrate surface with surface sites (—OH group) is exposed to the gaseous metal precursor (Trimethylaluminum, TMA) to carry out a selective chemisorb of the TMA until the surface sites are saturated. The ligand exchange by-product, methane (CH₄), is can be released from the substrate at high temperature.

The TMA precursor can not be adsorbed any more on the substrate surface when all the available surface sites (—OH group) are occupied, After that, an inert gas, argon (Ar, for example), is introduced to purge the excess precursor gas which has not reacted with substrate surface and ligand exchange by-products.

Next, pulsing an oxidant such as water (H₂O) on the surface to react with methyl-group (CH₃) on the substrate surface and generate free —OH groups and gaseous methane. The adjacent —OH groups and the gaseous methane perform a dehydration reaction to bring out the methyl group. After purging the excess precursor and by-products form the surface, a desired aluminum oxide film with atomic scale is formed and it is ready for the next ALD cycle. This procedure ensures excellent conformality along with large area of uniformity as well as digital thickness control by selecting the number of deposition cycle repeated.

Saturation behavior of an ALD reactant depends on many factors such as pulse/purge time, process pressure and process temperature, etc. the most important parameter to control the mechanism of an ALD process is the deposition temperature. Typically, a temperature region with a rather steady deposition rate, as known as ALD process window is observed, as shown in FIG. 1.

In general, the process window of ALD is a compromise temperature range between all involved precursors. The process temperatures of different precursors; the process temperature of each precursor is a temperature range between the precursor condensation temperature and the precursor decomposition temperature.

Some precursors that decompose in the high temperature region of a process window may harm the film quality and increase the impurity content of the film.

For the foregoing reason, the conventional ALD process temperature should be chosen within the ALD process window. Taking the TMA/H₂O process of ALD Al₂O₃ as an example, the reactive surface sites of TMA precursor, —OH groups, are decreased in number with increasing temperature, leading to the decrease of Al₂O₃ deposition rate. However, as higher deposition temperature can male the film more uniform and conformal, and contain lower impurity incorporation, which are mainly attributed to the faster H₂O diffusion as well as the more complete surface reactions at higher temperature Similar situations can also occur on the case of TMA/ozone (O₃) process, O₃ decomposition at high temperature can critically relate to the deposition rate, uniformity and step coverage performance of an ALD process.

Exactly as said, the process temperature is the most important factor in an ALD. The suitable process temperature range is specific for different precursors As above description, the conventional process window of the ALD is a compromise temperature range for different precursors so it is not easy to give consideration to ALD film properties and deposition rate in the meantime.

### SUMMARY

The present invention is directed to an atomic layer deposition method and the apparatus thereof, which satisfies the need of exactly temperature control in each ALD step.

In accordance with the embodiments of present invention, the atomic layer deposition apparatus includes a chamber and a heating and cooling device set in the chamber.

A wafer stage including a heater and a blowing duct is set in the chamber. The blowing duct can blow gas to diffuse heat of the heater and regulates the temperature of the chamber.

The heating and cooling device is mounted over the wafer stage opposite to the wafer. The heating and cooling device includes a plurality of heating units and a plurality of gas inlets. The gas inlets provide the reaction gas from outside of the chamber wherein each gas inlet is independent and separate from others.

Each heating unit includes a heat source and a cooler. The heat source generates thermal energy to increase the temperature of a deposited substrate in the chamber. The cooler is set around the heat source and to cool down the temperature of the heat source.

In conclusion, the atomic layer deposition method applies the atomic layer deposition apparatus to alternate the process temperature of the different ALD steps rapidly, whereby the atomic layer deposition performance can be improved by the precise control of the process temperature.

The process temperature of each step is determined in accordance with the specific precursor and the substrate surface used. In the case that a higher process temperature is needed, the heating units of the apparatus increase the temperature and maintains the temperature of the deposited substrate until the step is complete.

When a lower process window is needed for the next ALD step, the heating units are turned off, and the cooler rapidly cool down the temperature of the deposited substrate. In addition, the blowing duct blows a gas to the heater and the deposited substrate to cool the heater and the deposited substrate.

Because the process temperature is specific for different precursors, the embodiments of the present invention applying the atomic layer deposition apparatus to alternate the process temperature of each precursor. The apparatus alternates rapidly the deposition temperature ALD step; thereby the process temperature can be controlled precisely and simply.

It should be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the embodiment of the invention, and are incorporated in and constitute a part of this specification. The drawings illustrate embodiments of the invention and, together with the description, serve to explain the principles of the invention. In the drawings,

FIG. 1 is a scheme of the ALD process window in accordance with prior art;

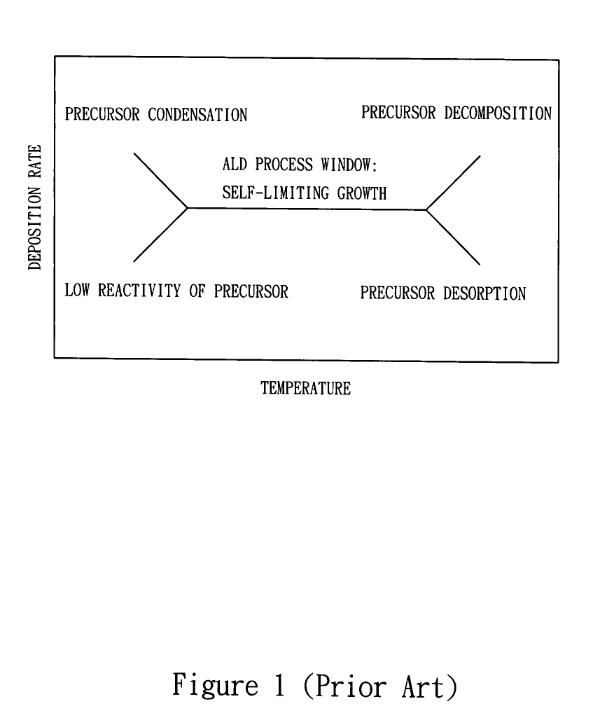

FIG. 2A is a schematic view of the atomic layer deposition apparatus in accordance with an embodiment of the present invention;

FIG. 2B is a schematic bottom view of a heating and cooling device of the atomic layer deposition apparatus in FIG. 2A;

FIG. 2C is an enlarged schematic sectional view of a heating unit of the heating and cooling device in FIG. 2B; and

FIG. 3 is a diagram of an ALD procedure in accordance with an embodiment of present invention.

### DESCRIPTION OF THE PREFERRED EMBODIMENTS

Reference will now be made in detail to the present embodiments of the invention, examples of which are illustrated in the accompanying drawings. Wherever possible, the same reference numbers are used in the drawings and the description to refer to the same or like parts.

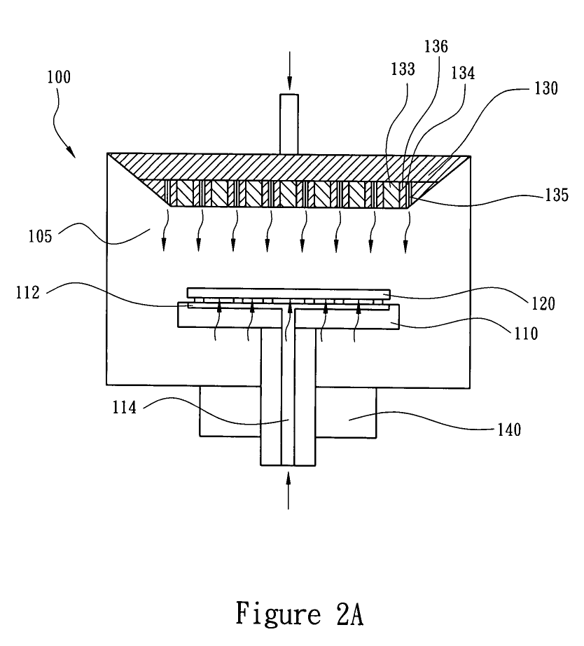

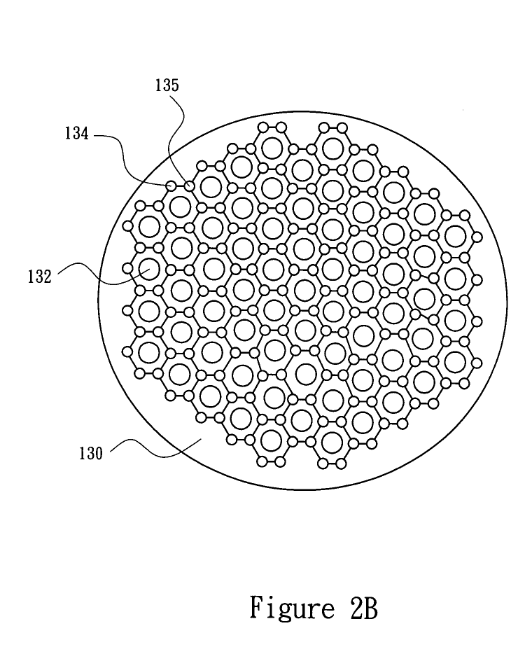

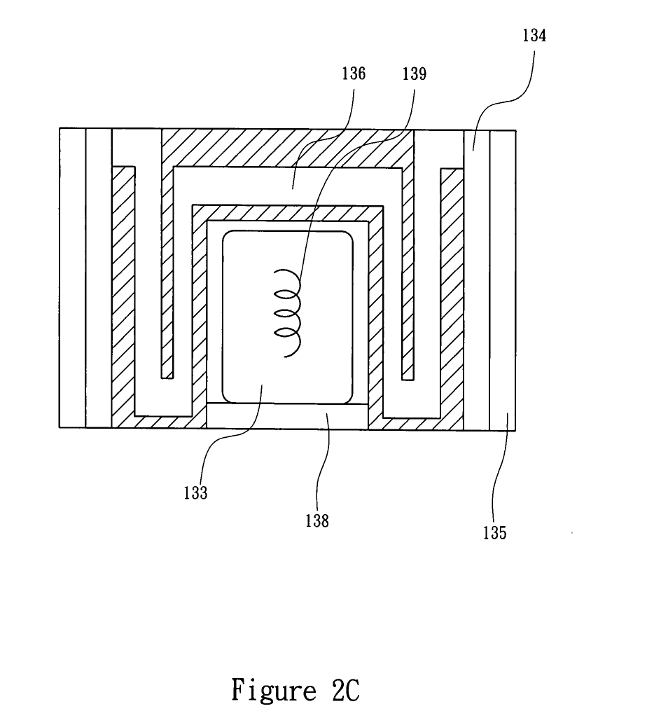

Refer to the FIG. 2A. FIG. 2A is is a schematic view of the atomic layer deposition apparatus in accordance with an embodiment of the present invention. The ALD apparatus 100 includes a chamber 105 and a temperature regulatory system set in the chamber 105. The temperature regulatory system includes a wafer stage 110 and a heating and cooling device 130.

The wafer stage 110 supports a wafer 120. The wafer stage 110 includes a heater 112 and a blowing duct 114. The blowing duct 114 imports a gas to diffuse the temperature of the heater 112 or to cool the heater 112 as indicated by the bottom arrow. The blowing duct 114 also assists in cooling the temperature of the heater 112 when necessary. According to the embodiment of the present invention, the gas imported from the blowing duct 114 is a gas with a high heat capacity, such as helium (He).

The heating and cooling device 130 is mounted over the wafer 120, and includes a plurality of heating units 132, a plurality of first gas inlets 134 and a plurality of second gas inlets 135. The heating units 132, the first gas inlet 134 and the second gas inlet 135 are arrayed to form a heating surface of the heating and cooling device 130. The gas inlets 134,135 pulse the reaction gas from outside of the chamber 105.

It should be noted that each first gas inlet 134 and the second gas inlet 135 is independent and separate from others. The upper arrow shown in FIG. 2A indicates the reaction gas pulsed direction. An exhauster 140 removes the excess reaction gas and heat.

In accordance with the embodiments of present invention, the reaction gas comprises Al(CH₃)₃, H₂O, O₃, O₂, SiCl₄, ZrCl₄, TiCl₄, TaCl₅, Hfl₄, HfCl₄, WF₆, SiH₆, NH3Hf(NEtMe)₄, Zr(NEtMe)₄, zirconium tetra-tert-butoxide, hafnium tetra-tert-butoxide, cyclopentadienyl strontium, cyclopentadienyl barium, and titanium isopropoxide. Refer to FIG. 2B and FIG. 2C. FIG. 2B is a schematic bottom view of a heating and cooling device of the atomic layer deposition apparatus in FIG. 2A. FIG. 2C is an enlarged schematic sectional view of a heating unit of the heating and cooling device in FIG. 2B. The heating units 132 are arrayed to form a heating surface of the heating and cooling device 130. Each heating unit 132 includes a heat source 133 and a cooler 136.

The heat source 133 generates the thermal energy to increase temperature of a deposited substrate 120 in the chamber 105. The cooler 136 cools down the temperature of the heat source 133 and comprises a passage and a working fluid. The passage surrounds the heat source 133 through which the working fluid passes to rapidly dissipate the heat of the. In one embodiment of present invention, the heat source 133 is a coil to generate the thermal energy. A protecting lens 138 covered with the heat source 133, and the protecting lens 138 is a sapphire lens or a ruby lens.

It should be noted that the shape, number or arrangement of each component of atomic layer deposition apparatus shown in FIG. 2A to FIG. 2C are as exemplification, other shapes, numbers or arrangements are possible. For example, the arrangement, number and shape of the heating units 132, the first gas inlets 134 and the second gas inlets 135 are not limited to the detail described in FIG. 2A to FIG. 2C, any appropriate disposition is available.

The atomic deposition method applies the ALD apparatus 100 to alternate the deposition temperature of the precursor pulse step and purge step rapidly, thereby the atomic layer deposition performance is improved. Because the process temperature is specific for different precursors and the ALD film quality is decided on the self-limiting film growth of the precursors, so the process temperature of each ALD step is decided in accordance with the film property demanded and specific precursor used.

According to the embodiments of the present invention, the heating units 132 of the ALD apparatus 100 increase the temperature of the chamber 105 when the higher temperature is needed. At the same time, the heater 112 of the wafer stage 110 heats the deposited substrate 120 and the blowing duct 114 blows a gas to regulate the temperature of the heater 112.

If a lower process temperature is needed for the next step, the heating units 132 are turned off; the blowing duct 114 puffs a gas to the heater 112 and the deposited substrate 120 to cool down the temperature of the deposited substrate 120. Further, the coolers 136 dissipate the heat of the heating units 132.

The TMA/H₂O pulse step of the Al₂O₃ deposition process is exemplified to explain the operational feature of the ALD apparatus 100. The ALD apparatus 100 is capable rapidly changing the process temperature for the pulse step and purge step of ALD process. The TMA pulse temperature is controlled within the lower range of the process window to prevent the desorption behavior of the surface reaction, and consequently improve the film properties. On the other hand, the H₂O pulse temperature is controlled within the higher range of the process window to accelerate the diffusion and decomposition of the H₂O.

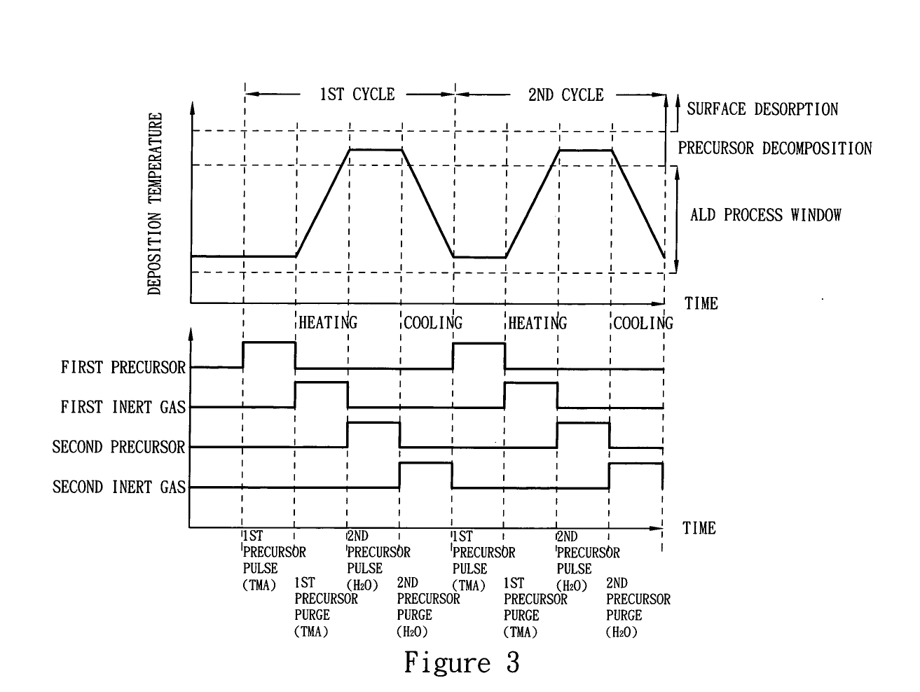

Refer to the FIG. 3. FIG. 3 shows the ALD procedure in accordance with an embodiment of the present invention. One cycle of the atomic layer deposition includes a first precursor pulse step (TMA pulse), a first precursor purge step (TMA purge), a second precursor pulse step (H₂O pulse) and a second precursor purge step (H₂O pulse). The ALD film thickness is controllable by selecting the number of deposition cycles repeated.

In the beginning of the cycle, the first precursor pulse step is performed. At least one deposited substrate 120 is provided in the chamber 105, and a first precursor is pulsed to the chamber 105 through the first gas inlets 134. The heating units 132 are turned off and the temperature of the deposited substrate 120 is predetermined at the lower range within a process window.

In this case, the lower limit of the process window is the precursor condensation temperature, and the higher limit of the process window is the precursor decomposition temperature. The term “higher range within a process window” designates a temperature range is approximately equal or beyond to the precursor decomposition temperature, and the term “lower range within a process window” designates a temperature range is lower relative to the precursor decomposition temperature.

The predetermined temperature is an optimal temperature range for performing a selective chemisorb between the first precursor and the reactive surface sites of the substrate.

The heater 112 of the wafer stage 110 is set at the lower temperature range within the ALD process window, and the blowing duct 114 puffs a gas to uniform the heat distribution over the deposited substrate 120. The first precursor TMA has high deposition rates at the lower temperature range within the ALD process window, wherein the reaction formula for the TMA selectively chemisorbed is:

Al—(OH)_{(solid)}+Al(CH₃)_{3(gas)}→Al—O—Al(CH₃)_{2(solid)}+CH_{4(gas)}.

Then, the first precursor purge step is performed. An inert gas is introduced into the chamber 105 through the first gas inlets 134 to purge the excess first precursor and by-products from the chamber. The heating units 132 are turned on to progressively increase the temperature of the chamber 105, and reach the temperature at a higher range within or out the process window after the purging of the chamber is complete. The predetermined temperature of the heater 112 is slightly lower than the process temperature for cooling the heater 132 promptly. The blowing duct 114 puffs an inert gas to cool down the temperature of the heater 112 wherein the inert gas is selected from the group consisting of Ar, He, and N₂. In embodiments of the present invention, an inert gas with higher heat capacity, such as helium (He), is suggested.

Next, the second precursor pulse step is performed. A second precursor (H₂O) is pulsed to the chamber 105 through the second gas inlets 135. The heating units 132 are turned on and the temperature of the deposited substrate 120 is kept at the higher range within the process window by the heater 112 to selectively chemisorb the second precursor. The predetermined temperature of the heater 112 is slightly lower than the process temperature for cooling the heater 132 promptly. The blowing duct 114 puffs an inert gas, such as helium, to cool down the temperature of the heater 112. The higher H₂O pulse temperature is able to accelerate the H₂O diffusion and complete the surface reactions of H₂O selectively chemisorbed, wherein the reaction formula for the H₂O selectively chemisorbed is:

Al(CH₃)_{3(gas)}+H₂O_{(gas)}→Al—OH_{(solid)}+CH_{4(gas)}.

Finally, a second precursor purge step is performed. The step of purging the second precursor is carried out when the available surface sites (—CH₃ group) are saturated. All of the reaction gases, such as the precursors and ligand exchange by-products, are removed from the chamber 105.

An inert gas is introduced into the chamber 105 through the second gas inlet 135 to clean the surface of the deposited substrate 120. Turn off the heating units 132 and start the cooler 136 to cool down the temperature of the heater 112, and the temperature of the chamber 105 is decreased progressively. The blowing duct 114 puffs an inert gas to cool down the temperature of the heater 112 wherein the inert gas is selected from the group consisting of Ar, He, and N₂. In embodiments of the present invention, an inert gas with higher heat capacity, such as helium (He), is suggested.

According to embodiments of the present invention, further repeating one or more the ALD cycles to grow an ALD film with desired thickness. The ALD apparatus alternates the deposition temperature of each pulse step rapidly and the purge step improves the atomic layer deposition performance.

Although the present invention has been described in considerable detail with reference to certain preferred embodiments thereof, other embodiments are possible. Therefore, the spirit and scope of the appended claims should not be limited to the description of the preferred embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of atomic layer deposition, comprising:
(a) providing a substrate in a chamber, wherein the substrate has a temperature at a lower range within a process window; (b) pulsing a first precursor to the chamber, and a selective chemisorption of the first precursor can happen on surface reaction sites of the substrate; (c) purging the excess first precursor and by-products from the chamber, and turning on a plurality of heating units to raise the temperature of the substrate to a higher range within the process window after purging the chamber;
(d) pulsing a second precursor to the chamber to make the selective chemisorption of second precursor to occur at the reactive surface sites of the substrate wherein the temperature of the substrate is kept at the higher range within the process window by using the heating units; and
(e) purging the excess second precursor and by-products from the chamber, and turning off the heating units to cool down the temperature of the substrate to the lower range within the process window, wherein each of the heating units is cooled by a cooler and the temperature of the substrate is decreased by a gas puffed from a blowing duct.

2. The method of claim 1, wherein the first precursor is selected from the group consisting of Al(CH₃)₃, H₂O, O₃, O₂, SiCl₄, ZrCl₄, TiCl₄, TaCl₅, Hfl₄, HfCl₄, WF₆, SiH₆, NH3Hf(NEtMe)₄, Zr(NEtMe)₄, zirconium tetra-tert-butoxide, hafnium tetra-tert-butoxide, cyclopentadienyl strontium, cyclopentadienyl barium, and titanium isopropoxide.

3. The method of claim 1, wherein step (c) comprises introducing an inert gas to bring out the excess first precursor and by-product from the chamber.

4. The method of claim 3, wherein the inert gas is selected from the group consisting of Ar, He, and N₂.

5. The method of claim 1, wherein the second precursor is selected from the group consisting of Al(CH₃)₃, H₂O, O₃, O₂, SiCl₄, ZrCl₄, TiCl₄, TaCl₅, Hfl₄, HfCl₄, WF₆, SiH₆, NH3Hf(NEtMe)₄, Zr(NEtMe)₄, zirconium tetra-tert-butoxide, hafnium tetra-tert-butoxide, cyclopentadienyl strontium, cyclopentadienyl barium, and titanium isopropoxide.

6. The method of claim 1, wherein step (d) further comprises maintaining simultaneously the temperature of the substrate by a heater, and the blowing duct introduces a gas to distribute the heat generated by the heater.

7. The method of claim 6, wherein the gas is puffed from the blowing duct comprises helium.

8. The method of claim 1, further comprising
pulsing a variety of precursor gas follows the step (e); and
regulating the temperature of the substrate in accordance with the processes described as step (e).

9. The method of claim 1, wherein the step (e) comprises introducing an inert gas to bring out the excess second precursor and by-products from the chamber.

10. The method of claim 9, wherein the inert gas is selected from the group consisting of Ar, He, and N₂.

11. The method of claim 1, further comprising repeating the step (b) to (e) to grow a film with desired thickness.

12. An atomic layer deposition apparatus, comprising:
a chamber;
a wafer stage set in the chamber and comprising a heater and a blowing duct wherein the blowing duct diffuses the heat of the heater;
a heating and cooling device mounted over the wafer stage and comprising a plurality of heating units, each heating unit comprising
a heat source adapted to increase a temperature of a deposited substrate in the chamber;
a cooler set around the heat source to cool down the heat source and the deposited substrate; and
a plurality of gas inlets adapted to introduce a variety of reaction gases to the chamber, wherein each gas inlet is independent and separate from the others.

13. The apparatus of the claim 12, wherein the heat source comprising an electrothermal coil.

14. The apparatus of the claim 12, wherein the heat source comprising a protecting lens.

15. The apparatus of the claim 14, wherein the protecting lens is a ruby lens.

16. The apparatus of the claim 14, wherein the protecting lens is a sapphire lens.

17. The apparatus of the claim 12, wherein the blowing duct is adapted to introduce helium.
